(19) United States
(12) Patent Application Publication
(10) Pub. No.: US 2025/0221053 A1
(43) Pub. Date: Jul. 3, 2025

(54) INTEGRATED CIRCUIT DEVICE WITH ZENER DIODE WITH REDUCED LEAKAGE AND/OR INCREASED BREAKDOWN VOLTAGE

(71) Applicant: Texas Instruments Incorporated, Dallas, TX (US)

(72) Inventors: Aarthi Rao, Coppell, TX (US); Natasha Lavrovskaya, Sunnyvale, CA (US); Alexei Sadovnikov, Sunnyvale, CA (US); James Robert Todd, Plano, TX (US)

(21) Appl. No.: 18/401,287

(22) Filed: Dec. 29, 2023

(51) Int. Cl. H01L 27/02; H01L 21/02; H01L 27/06; H01L 29/66; H01L 29/78; H01L 29/866

(52) U.S. Cl. CPC H10D 89/611; H01L 21/02595; H10D 8/022; H10D 8/25; H10D 84/158; H10D 84/811

(57) ABSTRACT

A method forms an integrated circuit, by steps including forming a polysilicon layer having a first side over a semiconductor substrate having a top surface, forming over the semiconductor substrate a first resist layer having a second side spaced apart from the first side, forming a diode well extending into the semiconductor substrate between the first side and the second side, the diode well having a first conductivity type, forming over the semiconductor substrate a second resist layer having a third side, and forming a diode terminal extending into the semiconductor substrate between the first side and the third side, the diode terminal having an opposite second conductivity type and extending from the diode well along the top surface.

### CROSS-REFERENCE TO RELATED APPLICATION

Not applicable.

### TECHNICAL AREA

Described examples relate to semiconductor integrated circuits (IC) and fabrication, and more particularly, but not exclusively, to an IC that includes an integrated Zener diode with other devices, such as a metal oxide semiconductor (MOS) transistor and/or a laterally diffused metal oxide semiconductor (LDMOS) transistor.

### BACKGROUND

IC fabrication typically considers and balances tradeoffs among various factors, including any one or more of IC size, cost, complexity, performance, and yield, among others. These factors can be further complicated when an IC includes differing device types, as sometimes an adjustment to a factor, relative to one of those devices, can have a tradeoff impact on another device(s). These tradeoffs may exist, for example, in an IC with a Zener diode and other devices, as factors in constructing the other devices can undesirably affect targeted Zener diode operational parameters, such as breakdown voltage or leakage current. For example, in some ICs, a Zener diode and LDMOS transistor may be included, where the transistor permits higher power application and operations and the Zener diode is coupled to the transistor in a manner to permit reverse breakdown of the Zener diode, in an instance of increased voltage on the LDMOS transistor, so as to protect against potential damage to the transistor gate oxide. However, some baseline manufacturing methods may inefficiently require additional steps or considerations targeted at only one or the other of the LDMOS transistor or the Zener diode.

While the preceding may have implementation in various baseline devices, this document provides examples that may improve on certain of the above concepts, as detailed below.

### SUMMARY

In an example, a method of forming an integrated circuit is described. The method includes forming a polysilicon layer having a first side over a semiconductor substrate having a top surface, forming over the semiconductor substrate a first resist layer having a second side spaced apart from the first side, forming a diode well extending into the semiconductor substrate between the first side and the second side, the diode well having a first conductivity type, forming over the semiconductor substrate a second resist layer having a third side, and forming a diode terminal extending into the semiconductor substrate between the first side and the third side, the diode terminal having an opposite second conductivity type and extending from the diode well along the top surface.

Other aspects are also described and claimed.

### BRIEF DESCRIPTION OF THE DRAWINGS

FIGS. 1 through 9 are partial cross-sectional views representing successive fabrication stages and resultant structures of an IC semiconductor structure.

FIG. 10 is a plan view of another example diode.

FIG. 11 is a flow diagram of an example method for manufacturing a semiconductor structure.

### DETAILED DESCRIPTION

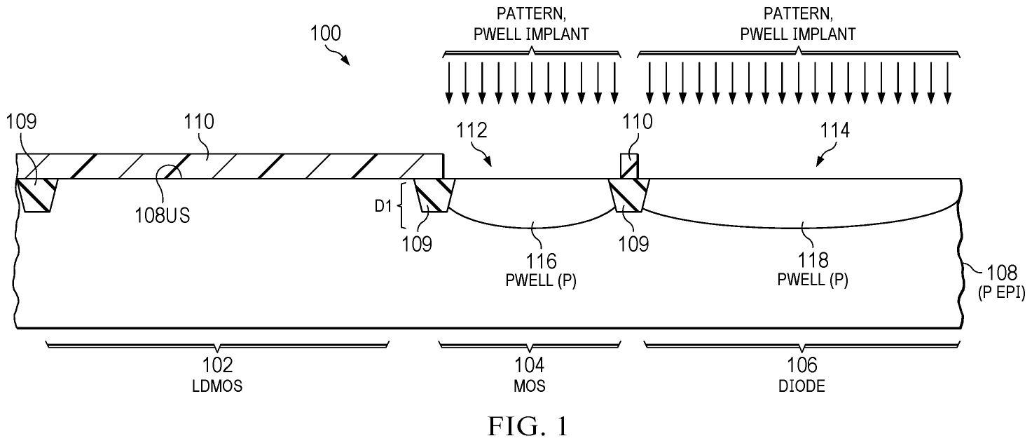

FIGS. 1 through 9 are cross-sectional views representing successive fabrication stages and resultant structures of a semiconductor structure 100, e.g. a portion of an IC. Ultimately, the semiconductor structure 100 will include IC devices, such as an LDMOS transistor, a MOS transistor, and a diode (e.g., Zener diode), so FIG. 1, and others, show an LDMOS transistor area 102, a MOS transistor area 104, and a diode area 106, in which each of the respective devices is formed. As one example, the IC may provide an LDMOS transistor operating at a voltage greater than associated with the MOS transistor, for example with the LDMOS operating at 10 volts or more, the MOS transistor operating at 5 volts or less, and a diode may be proximate either the MOS or the LDMOS transistor, for example for voltage-protection purposes. Still further, in addition to the diode, the IC may include numerous other devices (not shown) that function in relation to the transistor. Such devices may be isolated at the substrate level from the structures shown in FIG. 1 (and other later figures), for example via field oxides, formed for example using either a shallow trench isolation (STI) or local oxidation of silicon (LOCOS) process, and may be connected at an interconnect level with the structures shown in FIG. 1.

Starting with FIG. 1, the semiconductor structure 100 includes a semiconductor substrate 108, for example as part of a silicon wafer, and with isolation regions 109 formed between the above-introduced device areas. Such a wafer typically includes multiple locations, each corresponding to a same or different IC on the wafer, so the illustration of FIG. 1 (and later figures) can be repeated in each wafer IC location. The wafer typically provides either a P-type or N-type semiconductor, and the substrate 108 can represent a portion of the bulk wafer or a region (e.g., a well or buried layer) formed in connection with the wafer. In the illustrated example, the substrate 108 is a P-type epitaxial (epi) layer. A mask (e.g., resist) layer 110, for example using a photolithography process as may also be the case for other masks identified below, is formed over selective locations across an upper surface 108US. The mask layer 110 includes first and second openings 112 and 114, each in a respective area where an implant is to be performed. An implant is performed through the first opening 112 in a portion of the MOS transistor area 104 and through the second opening 114 in a portion of the diode area 106, for example using a P-type dopant implant to form respective PWELL regions (or more generally well regions) 116 and 118. Each of the PWELL regions 116 and 118 may have a dopant concentration in a range from 1e16/cm³ to 3e17/cm³, and a maximum depth D1 (shown in the vertical dimension), extending from the upper surface 108US and into the substrate 108, in a range of 0.5 μm to 1.5 μm.

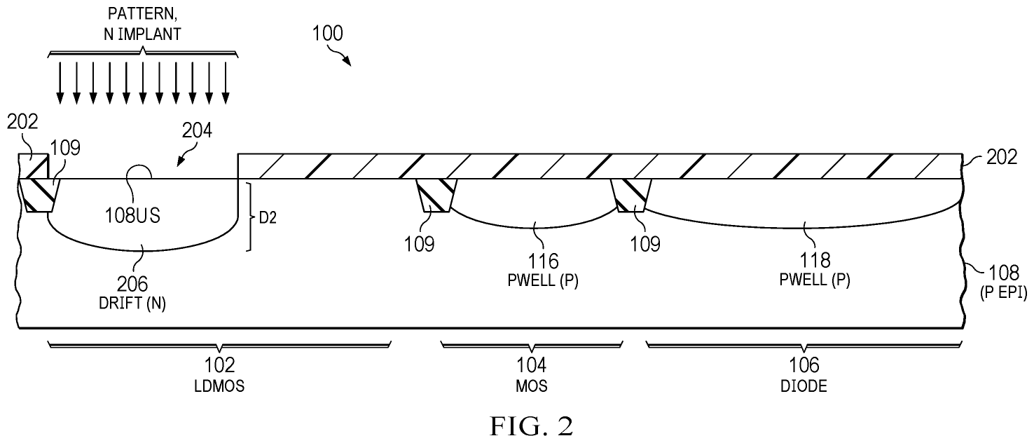

In FIG. 2, the FIG. 1 mask layer 110 is removed and a mask layer 202 is formed, and it is patterned to form an opening 204 therein. An implant is performed through the opening 204 in a portion of the LDMOS transistor area 102, for example using an N-type dopant implant to form respective a drift region 206, in the substrate 108. The drift region 206 may have a dopant concentration in a range from 3E15/cm³ to 1E17/cm³, and a maximum depth D2 (shown in the vertical dimension), extending from the upper surface 108US and into the substrate 108, in a range of 0.2 μm to 2 μm.

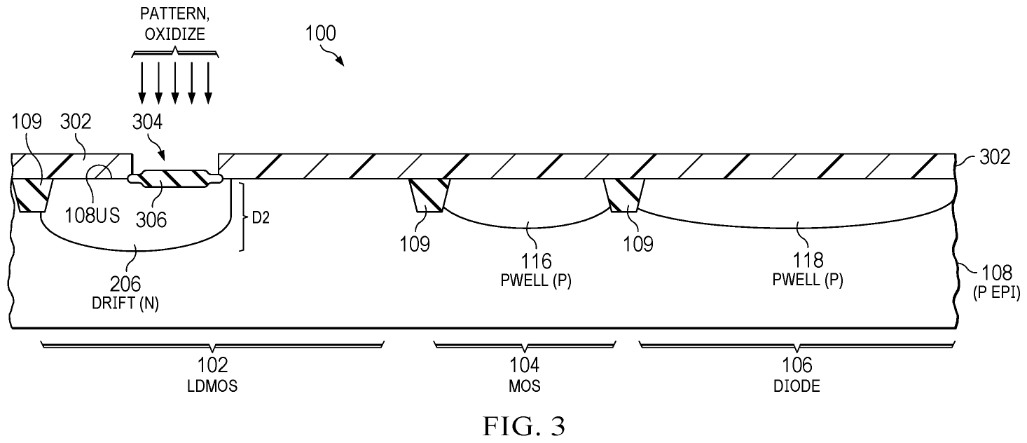

In FIG. 3, the FIG. 2 mask layer 202 is removed and a mask layer 302 such as a layer of SiN is formed, and it is patterned to form an opening 304 therein. A thick LOCOS structure 306 is formed through the opening 304 in the etch mask layer 302 and above the drift region 206. Generally, the LOCOS structure 306 may be formed by oxidizing the portion of the upper surface 108US that is exposed through the opening 304. As shown, the LOCOS structure 306 may include a central portion having, in the vertical dimension, a greater depth toward its central area, as opposed to in the area around its lateral or peripheral edges, which form what is sometimes referred to as “bird's beak.”

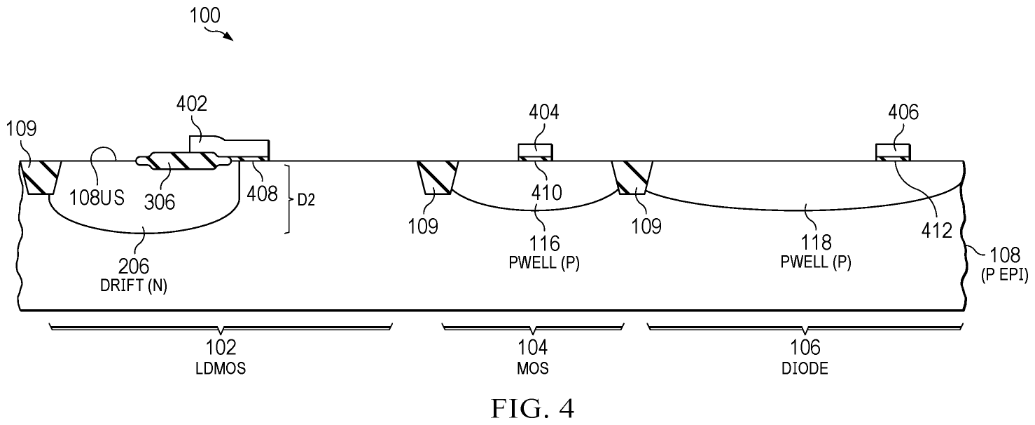

In FIG. 4, the FIG. 3 mask layer 302 is removed and polysilicon (poly) and related structures have been formed from a polysilicon layer in each of the LDMOS transistor area 102, the MOS transistor area 104, and the diode area 106. First, a thin insulator layer is formed (only portions of which remain in FIG. 4), for example by growing or depositing an insulator, such as an oxide, over exposed portions of the upper surface 108US. Next, a poly layer (only portions of which remain in FIG. 4) is formed over the insulator layer. The deposited poly layer may be in-situ or subsequently doped. The poly and thin insulator layers are patterned and etched to form resultant poly structures 402, 404, and 406, separated from the upper surface 108US, by a remaining and respective insulator portion 408, 410, and 412, each in a respective one of the LDMOS transistor area 102, the MOS transistor area 104, and the diode area 106. With respect to the poly structure 402, one vertical end provides a first sidewall above the LOCOS structure 306, and the other vertical end provides a second sidewall positioned laterally beyond the vertical edge of the drift region 206. The combination of the poly structure 402 and the insulator portion 408, in combination also with an area where the poly structure 402 overlaps the thick LOCOS structure 306, may function as an LDMOS transistor gate and respective gate dielectric. The combination of the poly structure 404 and the insulator portion 410 may function as a MOS transistor gate and respective gate dielectric. As further described below, the combination of the poly structure 406 and the insulator portion 412 may function as an implant hard mask, in connection with a diode being formed in the diode area 106.

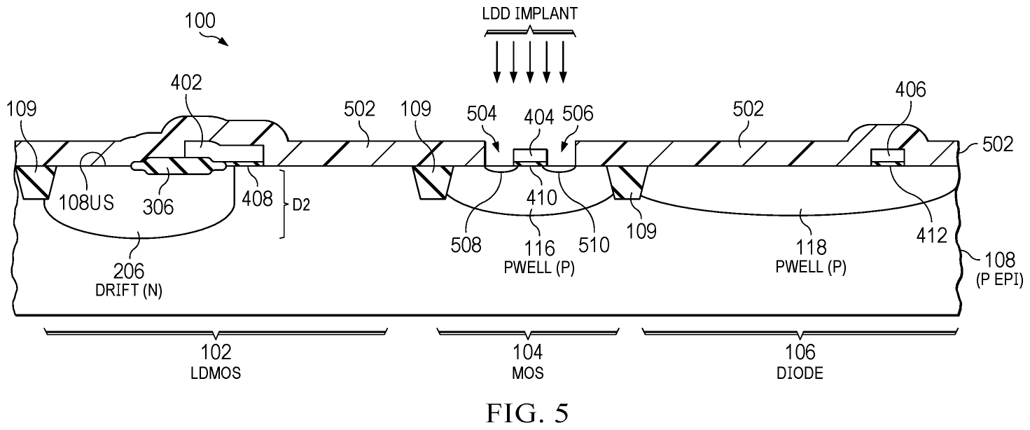

In FIG. 5, a mask layer 502 is formed over the upper surface 108US, and it is patterned to form first and second openings 504 and 506 therein, with both openings located in the MOS transistor area 104. A relatively light dopant implant, commonly referred to as a lightly doped drain (LDD) implant, is performed through the first and second openings 504 and 506, forming corresponding LDD regions 508 and 510 below the upper surface 108US and that self-align to the insulator portion 410. The LDD implant is typically provided at an energy lower than a separate (described later) n-type or p-type source/drain implant, and it is selected of a dopant type corresponding to the desired conductivity type of the transistor being formed in the MOS transistor area 104. For example, for an n-type MOS (NMOS) transistor, the LDD implant is of n-type dopants (e.g., phosphorous and/or arsenic pocket implants, with an optional germanium pre-amorphizing implant (PAI)), for example with phosphorous at an energy in a range from 5 keV to 80 ke V and with a dose in a range of 1e13 to 3e14 atoms/cm², or arsenic at an energy in a range from 10 keV to 100 keV and with a dose in a range of 1E14 to 1E15 atoms/cm² and with a 0 to 35 degree tilt with two or four rotations. As an alternative example, for a p-type MOS (PMOS) transistor, the LDD implant is of p-type dopants (e.g., BF₂ (difluoroboron), boron, and/or indium with an optional germanium PAI), for example with BF₂ at an energy in a range from 5 keV to 50 keV and with a dose in a range of 5E13 to 5E14 atoms/cm², boron at an energy in a range from 2 keV to 20 ke V and with a dose in a range of 5E13 to 5E14 atoms/cm², and/or indium at an energy in a range from 2 keV to 15 keV with a dose in a range of 1E13 to 5E14 atoms/cm², optionally with a germanium PAI at an energy in a range from 5 keV to 20 ke V with a dose in a range of 1e14 to 5e14 atoms/cm². A PMOS LDD also may include an arsenic and/or antimony pocket implant in a range from 20 ke V to 60 ke V with a dose in a range of 1E13 to 1E14 atoms/cm². During the LDD implant, the poly structures 402 and 406 may or may not be masked.

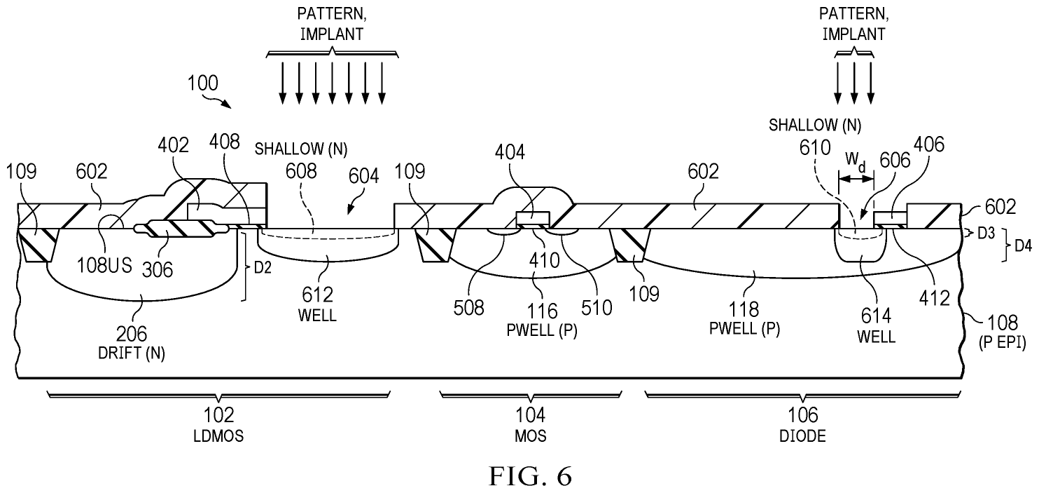

In FIG. 6, the FIG. 5 mask layer 502 is removed and a mask layer 602 (e.g., photoresist) is formed over the upper surface 108US, and it is patterned to form first and second openings 604 and 606 therein, with the first opening 604 in the LDMOS area 102 and the second opening 606 in the diode area 106. While the first opening 604 is above a portion of the LDMOS transistor area 102, it is laterally spaced apart from the drift region 206. Accordingly, a subsequent implant through the first opening 604 will provide a DWELL structure of targeted position, for example self-aligned to the vertical edge of the poly structure 402, for purposes of operation of the LDMOS transistor. Also in this regard, the width of the first opening 604, so as to allow for such a DWELL, is in a range of 0.5 μm to 1.0 μm. Separately, the second opening 606 is in the diode area 106, and it exposes an area of the upper surface 108US defined between two different types of structures, namely, on one vertical edge by the mask layer 602 and on another vertical edge provided by a sidewall of the poly structure 406 that was shown as formed in FIG. 4, concurrently with other poly structures 402 and 404. Further, the width of the second opening between those two vertical edges, is shown as w_{d} and may be controlled to a range from 30 nm to 300 nm and may provide important benefits, further described below. Two sets of implants are thereafter performed, for example sequentially and in either order, through the first and second openings 604 and 606, as described below, so note that each of those implants, to the extent they pass through the second opening 606, relies in part on the poly structure 406 serving as an implant hard mask, as that poly structure defines one edge of the second opening 606 (the other edge provided by the mask layer 602).

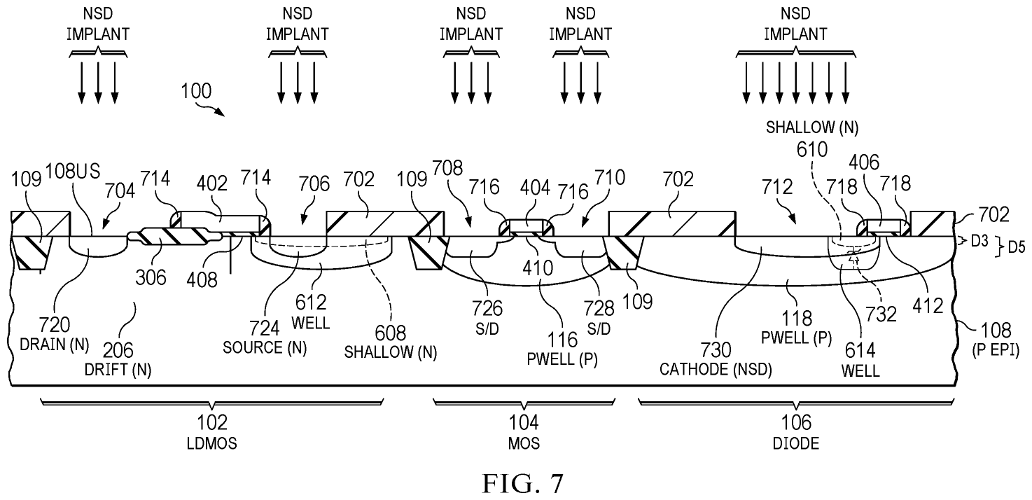

One implant performed through both the first and second openings 604 and 606 uses a dopant type that is the same of that used for the drift region 206 and the opposite as used for the PWELL region 118. Accordingly, in the present example in which the drift region 206 is N-type and the PWELL region 118 is P-type, then the FIG. 6 implant is N-type, for example using arsenic. Further, the result of this FIG. 6 implant is termed a shallow implant region in that the implant has an implant energy lower than that used for a deeper implant to be described and also through the same openings 604 and 606. For example, the FIG. 6 shallow implant dose can be in a range from 1.0E14 atoms/cm² to 2.0E14 atoms/cm² (e.g., 1.4E14 atoms/cm²) and at an energy in a range from 5 keV to 10 keV (e.g., 8 keV). The shallow implant forms a shallow well region 608 in the substrate 108 that is generally aligned with the first opening 604, and it also forms a shallow well region 610 in the substrate 108 that is generally aligned with the second opening 606. In an example, each of the shallow well region 608 and the shallow well region 610 is thereby formed concurrently, with a same implant, and with a depth D3 extending into the substrate 108. The depth D3 is selected based on a depth D5 of a subsequently-formed source/drain (see D5, FIG. 7), where D3 is approximately fifty percent (50%) or less of D5. For example, where D5 may be in a range from 60 nm to 200 nm, then correspondingly and respectively D3 may be in a range from 30 nm to 100 nm.

Another implant performed through both the first and second openings 604 and 606 uses a dopant type that is the opposite of that used for the drift region 206 and the same as used for the PWELL region 118, which in the current example is P-type, so as to form a transistor well region 612 and a diode well region 614. This implant forms the well regions 612 and 614 as deeper and below the respective shallow well regions 608 and 610, using a greater energy than the shallow well implant. In various examples the well regions 612 and 614 are double-diffused wells (DWELLs). The deeper implant targets a depth D4, which may be in a range from 300 nm to 500 nm. The deeper implant uses doses and energies consistent with these goals, for example in a range of 1E13 atoms/cm² to 6E13 atoms/cm², and at an energy in a range from 20 keV to 50 keV (e.g., 3E13 atoms/cm² at an energy of 32 keV).

In FIG. 7, the FIG. 6 mask layer 602 has been removed and a mask layer 702 (e.g., photoresist) is formed over the upper surface 108US, and it is patterned to form first through fifth openings 704, 706, 708, 710, and 712 therein, with certain of these openings in each of the LDMOS area 102, the MOS area 104, and the diode area 106. Sidewall spacers 714 have been formed along the sidewalls of the poly structure 402, sidewall spacers 716 have been formed along the sidewalls of the poly structure 404, and sidewall spacers 718 have been formed along the sidewalls of the poly structure 406. The sidewall spacers 714, 716, and 718 may be formed, for example, by formation of an oxide and/or nitride layer above and along at least the sidewalls of each poly structure, followed by an appropriate etch, so as to leave remaining portions of the oxide and/or nitride later as the sidewall spacers.

FIG. 7 also illustrates a source/drain implant, which in the example is with N-type dopants and correspondingly termed an NSD implant. The NSD implant, for example using arsenic (or phosphorous or antimony), is in connection with the source/drain functionality of the LDMOS transistor in the LDMOS transistor area 102 and of the NMOS transistor in the MOS transistor area 104. The implant forms N-type regions in the substrate 108 through each of the first through fifth openings 704, 706, 708, 710, and 712. The NSD implant can be in a range from at 1.0E15 atoms/cm² to 1.6E15 atoms/cm² and at an energy in a range from 20 keV to 30 keV, thereby implanting dopants to a depth D5, which recall from above may be in a range from 60 nm to 200 nm. As a result, the N-type implant forms a drain 720 and source 724 for the LDMOS transistor and first and second source/drain (S/D) regions 726 and 728 for the MOS transistor. The N-type implant also forms an N-type region 730. The N-type region 730 (combining with the N-type shallow well region 610) interfaces, or forms a metallurgical interface, with the P-type material of the diode well region 614, thereby providing a PN junction 732 between the two, with that junction illustrated in part by a schematic diode symbol with a dotted outline, as between the diode well region 614 and the N-type region 730. The N-type region 730 portion that extends away from the shallow well region 610 along the upper surface 108US may operate as a first terminal of the diode 106.

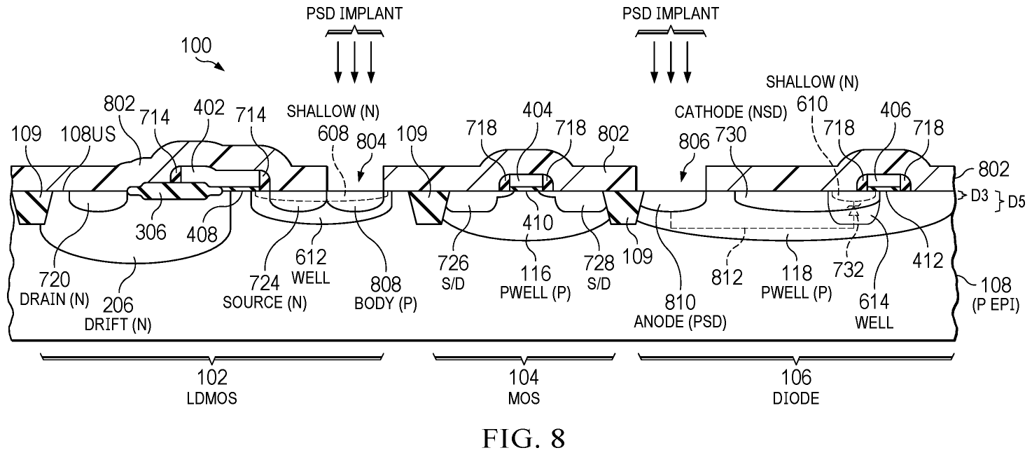

In FIG. 8, the FIG. 7 mask layer 702 has been removed and a mask layer 802 is formed over the upper surface 108US, and it is patterned to form a first opening 804 in the LDMOS area 102 and a second opening 806 in the diode area 106. An implant is then performed, of a complementary type to FIG. 7; accordingly, where the FIG. 7 uses N-type dopant, the FIG. 8 implant is P-type, again for example using boron. The FIG. 8 implant may be referred to as a PSD implant, that is, implanting P-type dopant and in connection with transistors either shown, or other than those shown, and that may require P-type source/drain or other regions. The FIG. 8 implant can be in a range from at 1E15 atoms/cm² to 10E15 atoms/cm² and at an energy in a range from 5 keV to 10 keV and also to a depth of D5. The FIG. 8 P-type implant forms a P-type body region 808 through the first opening 804 and in the transistor well region 612. Further, the FIG. 8 P-type implant forms a P-type region 810 through the second opening 806 and in the PWELL region 118. The P-type region 810 is spaced apart from the N-type region 730, in that the PWELL region 118 extends to the surface 108US between the P-type region 810 and the N-type region 730. The P-type region 810 provides a same-dopant-type conductivity path 812, shown by a dotted line through the PWELL region 118 (and possibly also a portion of the substrate 108) and to the diode well region 614, such that electrical contact may be made to the P-type region 810 as the anode of the PN junction 732. The P-type region 810 may operate as a second terminal of the diode 106.

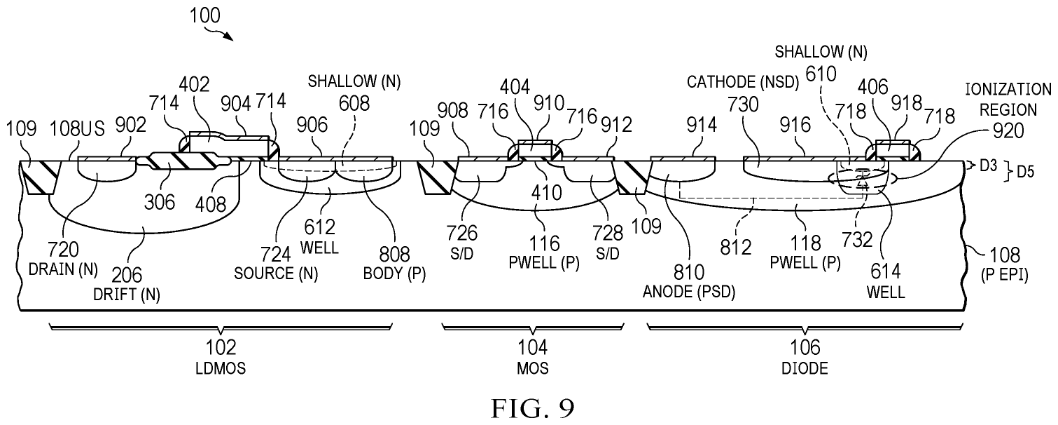

In FIG. 9, the FIG. 8 mask layer 802 has been removed. Thereafter, connections may be made to the LDMOS transistor in the LDMOS transistor area 102, to the MOS transistor in the MOS transistor area 104, and to the diode in the diode area 106, either as between the devices or to other devices. To facilitate such connections. For example, in FIG. 9, silicide conductive regions 902, 904, 906, 908, 910, 912, 914, 916, and 918 are formed along selected semiconductor surfaces, for example respectively and laterally along surfaces of the drain 720, the source 724 and the body region 808, the S/D region 726, the S/D region 728, the P-type region 810, the N-type region 730, and the poly structures 402, 404, and 406. In this regard, an electrical path through the PN junction 732 may be realized by electrical contact to the silicide conductive region 914 as a diode anode and to the silicide conductive region 916 as a diode cathode. Along that electrical path, and where the P-type material of the diode well region 614 interfaces with the N-type material of the N-type region 730, an ionization region 920 is presented, which represents a location where diode breakdown (or impact ionization) can occur due to the P-type/N-type (PN) junction or interface. Particularly, with the formation of the diode well region 614, it presents a lower P-type dopant concentration, as compared to the PWELL region 118 in which the diode well region 614 is formed. As a result, in the ionization region 920, the relatively higher P-type dopant concentration from the diode well region 614 in the area of the ionization region 920, that is, at the PN junction 732 of the diode well region 614 to the N-type region 730, creates an area where one or more favorable attributes may be realized, including increasing breakdown voltage and/or decreasing the current leakage. Accordingly, either of both these attributes may be implemented without adding additional fabrication steps beyond those already implemented in the formation of other devices (e.g., in forming MOS and LDMOS transistors).

Also in FIG. 9, note that the ionization region 920 occurs at approximately the depth D5, that is, the depth of the PN junction 732 between the N-type region 730 and the P-type diode well region 614. Returning briefly to FIG. 6, recall the shallow well region 610 and the additional diode well region 614 are formed through the second opening 606, and that opening has a width w_{d}. With FIG. 9 having depicted the depth D5 at which the ionization region 920 occurs, note also that the FIG. 6 width w_{d} is, in one example, about equal to the depth D5. In other examples, however, w_{d} can range relative to the depth D5, for example as high as about 50% greater than D5 or as low as about 50% less than D5. In this context, “about” means±5%. This width-to-depth relationship is demonstrated by examples provided above, in which it has been stated that 60 nm≤D5≤200 nm, and 30 nm≤w_{d}≤300 nm, so that the smallest width of w_{d} is about 50% lower than the smallest depth of D5, and the largest width of w_{d} is about 50% greater than the largest depth of D5. Further, the depth D5, as relating to an NSD implant, is likely to have a depth pertaining to other devices in the semiconductor structure 100, such as the source 724 for the LDMOS transistor and first and second S/D regions 726 and 728 for the MOS transistor, and which nominally also establishes a depth for the N-type region 730 to serve as the cathode of the diode in the diode area 106. This depth may be in part constrained by the minimum accurate aperture size that may be achieved in photolithographic processes, such as in photoresist, as typically used to define the width of an implant opening, such as the FIG. 6 first opening 604, or the FIG. 7 first through fourth openings 704, 706, 708, and 710. However, in FIG. 6, note that the second opening 606, which has a width w_{d} that impacts the location of relatively high dopant concentration to be provided by the diode well region 614, is not so limited, as it is not bound on both lateral sides by photoresist, since on one side (e.g., the left in FIG. 6) it is has a boundary from a vertical edge of the mask layer 602, while on the opposite side (e.g., on the right in FIG. 6) it has a boundary from a vertical edge of the poly structure 406. Consequently, in FIG. 6 while a baseline DWELL implant process for other non-diode devices is performed, a relatively narrow width of the diode well region 614 may be achieved with the addition of the poly hard mask so that when the diode well region 614 is formed, it is self-aligned in part to the vertical sidewall of the hard mask poly structure 404. Accordingly, the width w_{d}, established in part by that hard mask poly structure 404, correspondingly adjusts the width and dopant concentration depth profile that forms the diode well region 614, and those factors support the subsequent formation, positioning, and behavior at the FIG. 7 PN junction 732 (as also shown as the FIG. 9 ionization region 920). And, this is achieved using poly (e.g., the poly structure 406) as a hard mask in conjunction with a traditional (e.g., photoresist) mask used for a DWELL implant for other devices (e.g., for the LDMOS transistor). Accordingly, when the N-type region 730 is subsequently formed as shown in FIG. 7, and as further illustrated in FIG. 9, the PN junction 732 provides a resultant ionization region 920 with a desirable relatively high P-type dopant concentration at that location, thereby increasing diode breakdown voltage and reducing diode leakage.

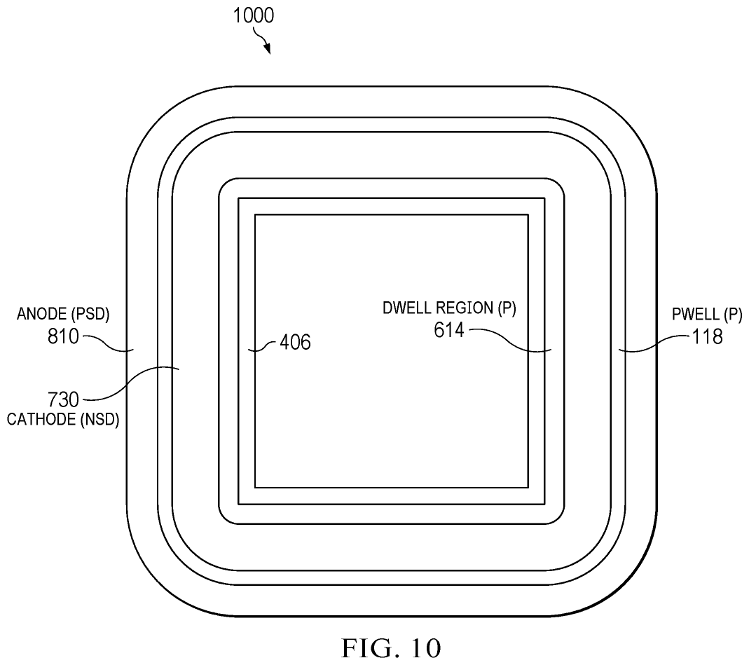

Lastly with respect to FIG. 9, additional electrical connections may be made, for example through metal layers and metal vias (not shown), formed generally atop the FIG. 9 structures and with contact to appropriate ones of the silicide conductive regions. FIG. 10 is a plan view of a diode 1000 that includes the diode portions of the FIG. 9 semiconductor structure 100. The diode 1000 is generally symmetric about the poly structure 406, which is shown as rectangular (or square). Accordingly, in each linear dimension where the poly structure 406 is formed, then outward from that dimension is shown the diode well region 614 (spaced apart from the poly structure 406 by an unreferenced sidewall spacer), and farther outward from the diode well region 614 is shown the N-type region 730 (cathode), and still farther outward from the N-type region 730 (cathode) is shown the P-type region (anode) 810. Accordingly, FIG. 10 depicts a different perspective of the preceding and as an example in which the N-type region (cathode) 730 fully surrounds the diode well region 614, and the P-type region 810 (cathode) fully surrounds the N-type region (cathode) 730.

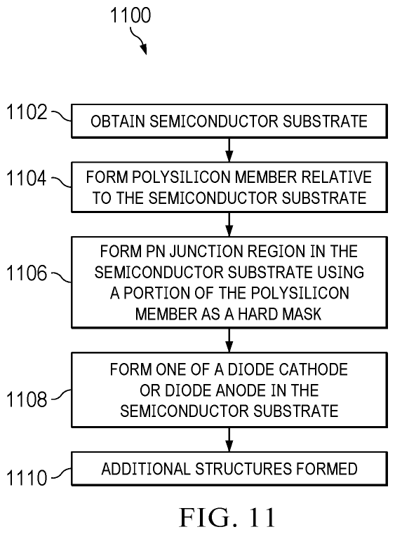

FIG. 11 is a flow diagram of an example method 1100 that summarizes various of the above-described steps for manufacturing the semiconductor structure 100, for example ultimately providing the structure 100 as shown in FIGS. 9 and 10. The method 1100 begins in a step 1102, in which the FIG. 1 semiconductor substrate 108 is obtained. The semiconductor substrate 108, at this stage, may be a bare wafer or may have one or more semiconductor features already formed on it. The semiconductor substrate 108 also includes one or more areas, or one or more electrical structures adjacent to such an area, in which it is desirable to form semiconductor or silicon including devices, for example such as a diode, and one or more of the LDMOS transistor and the MOS transistor. Next, in a step 1104, a polysilicon member, such as the FIG. 4 poly structure 406, is formed over a surface of the semiconductor substrate 108. Next in a step 1106, using a portion of the step 1104 polysilicon member as a hard mask, a PN junction region, such as the FIG. 6 diode well region 614, is formed in the semiconductor substrate 108. Next in a step 1108, one of a diode anode or a diode cathode, such as the FIG. 7 N-type region 730 (cathode) is formed in the semiconductor substrate 108. Thereafter, a step 1110 generally represents that, after the step 1108, additional structures may be formed, in connection with the diode (and possibly other devices and interconnections to these and other devices) associated with the step 1102 semiconductor substrate 108.

From the above, one skilled in the art will appreciate that examples are provided for semiconductor IC fabrication, for example with respect to an IC that includes a Zener diode with other devices, such as a MOS transistor and/or LDMOS transistor, which are formed at least in part using concurrent processing steps. Such examples provide various benefits, some of which are described above and including still others. For example, while certain dopant types have been described, complementary (opposite) conductivity types are also contemplated, thereby reversing the position of the diode anode and cathode. Other examples may implement other types of IC structures that lend processes that may be concurrently used to form the diode structures described herein. Accordingly, each of the diode breakdown voltage and leak may be favorably adjusted, without the use, for example, of an additional mask directed to only one or the other of these attributes. These benefits may be realized for more complex structures, of for multiple devices on the same substrate (and IC), thereby realizing scaled improvement across the device. Still additional modifications are possible in the described embodiments, and other embodiments are possible, within the scope of the following claims.

What is claimed is:

1. A method of forming an integrated circuit, comprising:
forming a polysilicon layer having a first side over a semiconductor substrate having a top surface;
forming over the semiconductor substrate a first resist layer having a second side spaced apart from the first side;
forming a diode well extending into the semiconductor substrate between the first side and the second side, the diode well having a first conductivity type;
forming over the semiconductor substrate a second resist layer having a third side; and
forming a diode terminal extending into the semiconductor substrate between the first side and the third side, the diode terminal having an opposite second conductivity type and extending from the diode well along the top surface.

2. The method of claim 1, wherein the diode terminal is a first diode terminal, and the diode well and the first diode terminal extend into a well region having the first conductivity type, further comprising forming a second diode terminal extending into the well region, the second diode terminal spaced apart from the first diode terminal and having the first conductivity type.

3. The method of claim 1, wherein the diode well is P-type and the diode terminal is N-type.

4. The method of claim 1, further comprising forming a shallow well between a PN junction and the top surface between the first and second sides, the shallow well overlapping the diode terminal and having the second conductivity type.

5. The method of claim 4, wherein a first depth of the shallow well is about half a second depth of the diode terminal.

6. The method of claim 4, wherein the shallow well has a depth about equal to one half a width between the first side and the second side.

7. The method of claim 1, wherein a width between the first side and the second side is in a range from 30 nm to 300 nm.

8. The method of claim 1, wherein a width between the first side and the second side is about equal to a depth of a metallurgical interface between the diode terminal and the diode well.

9. The method of claim 1, wherein a width between the first side and the second side is about a depth the diode terminal extends into the semiconductor substrate.

10. The method of claim 1, wherein an implant that forms the diode well also forms a DWELL of a transistor extending into the semiconductor substrate.

11. A method of forming an integrated circuit, comprising:
forming an exposed area of a semiconductor substrate between a resist mask and a polysilicon structure mask;
implanting N-type dopants and P-type dopants into the semiconductor substrate through the exposed area, thereby forming a PN junction below the exposed area; and
forming a diode terminal in the semiconductor substrate extending from the PN junction along a top surface of the semiconductor substrate.

12. The method of claim 11 wherein a width between the resist mask and the polysilicon structure mask is about a depth of the diode terminal.

13. The method of claim11, wherein the diode terminal is a first diode terminal having a first conductivity type, and further comprising forming a second diode terminal having an opposite second conductivity type spaced apart from the first diode terminal along the top surface.

14. The method of claim11, wherein the diode terminal has a first conductivity type, and further comprising forming a shallow well having the first conductivity type between the PN junction and the top surface.

15. The method of claim11, and further comprising forming a transistor over and extending into the semiconductor substrate, including forming a DWELL of the transistor using the resist mask.

16. An integrated circuit (IC), comprising:
a polysilicon member over a surface of a semiconductor substrate;
a PN junction below the surface and self-aligned to the polysilicon member; and
a diode contact extending away from the PN junction along the surface.

17. The IC of claim 16, wherein the diode terminal is a first diode terminal having a first conductivity type, and further comprising a second diode terminal having an opposite second conductivity type spaced apart from the first diode terminal along the surface.

18. The IC of claim 17, wherein a DWELL having the second conductivity type extends from the PN junction into the semiconductor substrate.

19. The IC of claim 16, wherein a first DWELL region having a conductivity type extends from the PN junction into the semiconductor substrate, and further comprising a MOS transistor extending into the semiconductor substrate, the MOS transistor including a second DWELL region having the conductivity type and a same depth as the first DWELL region.

20. The IC of claim 16, wherein the diode terminal having a conductivity type extends a first depth into the semiconductor substrate, and further comprising a MOS transistor including a source region and a drain region having the conductivity type and extending a same second depth into the semiconductor substrate.
